(19) United States
(12) Patent Application Publication
(10) Pub. No.: US 2023/0240063 A1
(43) Pub. Date: Jul. 27, 2023

(54) MEMORY DEVICE

(71) Applicant: TAIWAN SEMICONDUCTOR MANUFACTURING COMPANY, LTD., Hsinchu (TW)

(72) Inventors: Peng-Chun LIOU, Hsinchu (TW); Chia-En HUANG, Hsinchu (TW); Ya-Yun CHENG, Hsinchu (TW)

(73) Assignee: TAIWAN SEMICONDUCTOR MANUFACTURING COMPANY, LTD., Hsinchu (TW)

(21) Appl. No.: 17/584,716

(22) Filed: Jan. 26, 2022

(51) Int. Cl. H01L 27/108; H01L 29/10; H01L 29/417; H01L 29/24

(52) U.S. Cl. CPC H01L 27/10811; H01L 27/10855; H01L 29/1033; H01L 29/41775; H01L 29/24

(57) ABSTRACT

A memory cell includes a transistor and a capacitor. The transistor includes a gate electrode, a gate dielectric disposed over the gate electrode, a channel feature disposed over the gate dielectric and overlapping the gate electrode, a source electrode disposed over the channel feature and electrically connected to the capacitor, and two drain electrodes disposed over the channel feature. The drain electrodes are disposed at opposite sides of the source electrode. The channel feature has a first channel portion extending between and interconnecting one drain electrode and the source electrode, and a second channel portion extending between and interconnecting the other drain electrode and the source electrode. The gate electrode overlaps both of the first channel portion and the second channel portion of the channel feature.

### BACKGROUND

Semiconductor memory devices are widely used in integrated circuits (ICs) to store digital data for electronic applications. A conventional design of a memory cell includes a transistor and a capacitor connected to the transistor. A bit of data can be written into the capacitor when the transistor conducts, and the bit of data can be kept in the capacitor when the transistor is turned off.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view illustrating a first embodiment of a memory device according to this disclosure.

FIG. 2 is a schematic view illustrating a second embodiment of a memory device according to this disclosure.

FIG. 3 is a schematic view illustrating a third embodiment of a memory device according to this disclosure.

FIG. 4 is a plot illustrating some signals used to operate a memory cell in accordance with some embodiments.

FIGS. 5 through 19 are schematic view illustrating a process for fabricating a memory device in accordance with some embodiments.

FIG. 20 is a schematic view illustrating a fourth embodiment of a memory device according to this disclosure.

FIG. 21 is a schematic view illustrating a fifth embodiment of a memory device according to this disclosure.

FIG. 22 is a schematic view illustrating a sixth embodiment of a memory device according to this disclosure.

FIG. 23 is a schematic view illustrating a seventh embodiment of a memory device according to this disclosure.

FIG. 24 is a schematic view illustrating an eighth embodiment of a memory device according to this disclosure.

FIG. 25 is a schematic view illustrating a ninth embodiment of a memory device according to this disclosure.

FIG. 26 is a schematic view illustrating a tenth embodiment of a memory device according to this disclosure.

FIG. 27 is a plot illustrating some simulation results of off-state currents in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

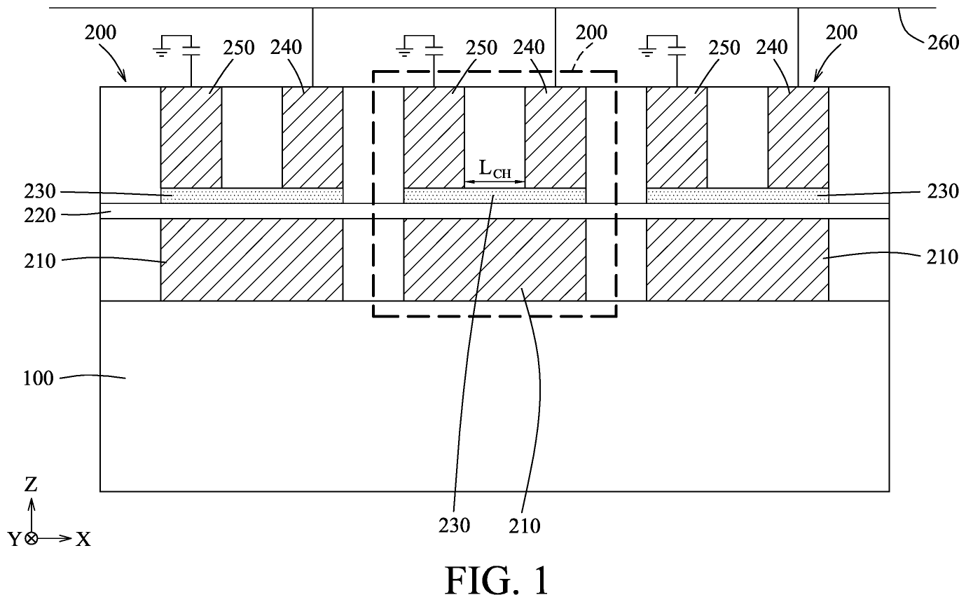

FIG. 1 illustrates a first embodiment of a memory device according to this disclosure. The memory device is formed on a substrate 100, and includes a plurality of memory cells, each of which includes a transistor 200 and a storage capacitor that is electrically connected to the transistor 200.

In the illustrative embodiment, the transistor 200 of each of the memory cells includes a gate electrode 210 formed on the substrate 100, a gate dielectric layer 220 formed over the gate electrode 210, a channel feature 230 formed over the gate dielectric layer 220 and overlapping the gate electrode 210 in a Z-axis direction, a drain electrode 240 formed over the channel feature 230, and a source electrode 250 formed over the channel feature 230. The drain electrode 240 and the source electrode 250 are spaced apart from each other in an X-axis direction that is transverse or perpendicular to the Z-axis direction. The channel feature 230 has a channel portion that extends between and interconnects the drain electrode 240 and the source electrode 250 (e.g., a portion extending from a right edge of the source electrode 250 to a left edge of the drain electrode 240 in FIG. 1), and that has a length in the X-axis direction defined as a channel length (L_{CH}) of the transistor 200. In other words, the channel length of the transistor 200 is defined as a distance between the drain electrode 240 and the source electrode 250 in the X-axis direction. For the transistors 200 that are arranged or aligned in the X-axis direction, the gate electrodes 210 of the transistors 200 are spaced apart from each other in the X-axis direction, the gate dielectric layers 220 of the transistors 200 are formed in the same layer and are connected together, the channel features 230 of the transistors 200 are formed in the same layer (referred to as a channel layer) and are spaced apart from each other (i.e., the channel layer common to the transistors 200 that are arranged or aligned in the X-axis direction is discontinuous), and the drain electrodes 240 of the transistors 200 are electrically connected to each other by a bit line 260 that extends in the X-axis direction. In other words, the bit line 260 interconnects the drain electrodes 240 of the transistors 200 that are arranged or aligned in the X-axis direction. For the transistors 200 that are arranged or aligned in the X-axis direction, the source electrode 250 of one of the transistors 200 is adjacent to and spaced apart from the drain electrode 240 of another one of the transistors 200. For the transistors 200 that are arranged or aligned in the X-axis direction, the drain electrode 240 of one of the transistors 200 is adjacent to and spaced apart from the source electrode 250 of another one of the transistors 200. For each of the memory cells, the source electrode 250 of the transistor 200 is electrically connected to the storage capacitor of the memory cell. Since the channel features 230 of the transistors 200 are separated from each other, a cell-to-cell leakage current can be minimized.

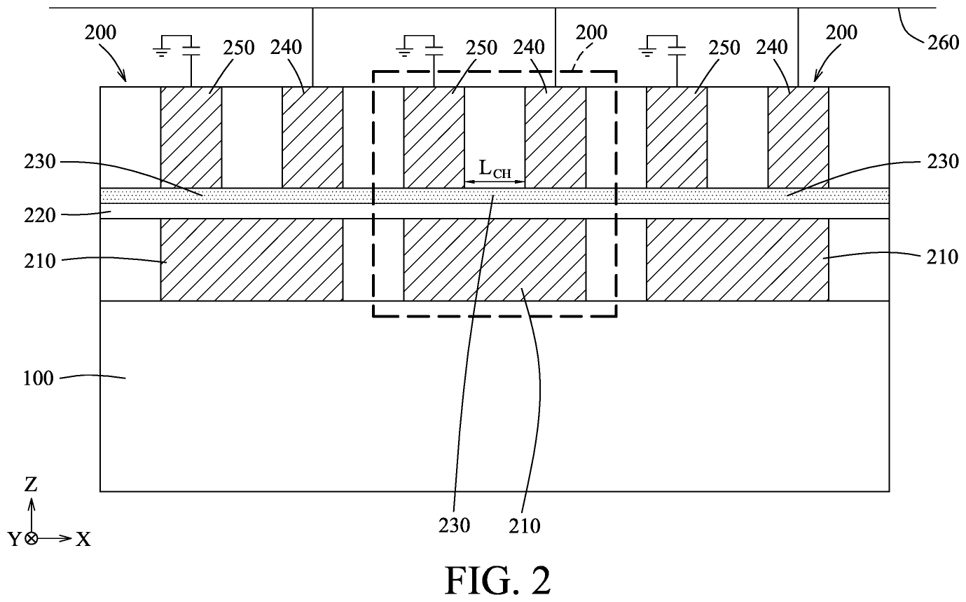

FIG. 2 illustrates a second embodiment of a memory device according to this disclosure. The second embodiment is similar to the first embodiment, but differs from the first embodiment in that, in the second embodiment, the channel features 230 of the transistors 200 that are arranged or aligned in the X-axis direction are connected together. In other words, the channel layer common to the transistors 200 that are arranged or aligned in the X-axis direction is continuous. As a result, it is not required for the second embodiment to etch the channel layer at a portion between two transistors 200 that are adjacent in the X-direction, which is usually narrow, thereby avoiding some process concerns (e.g., insufficient etching) that may occur in etching such a narrow portion.

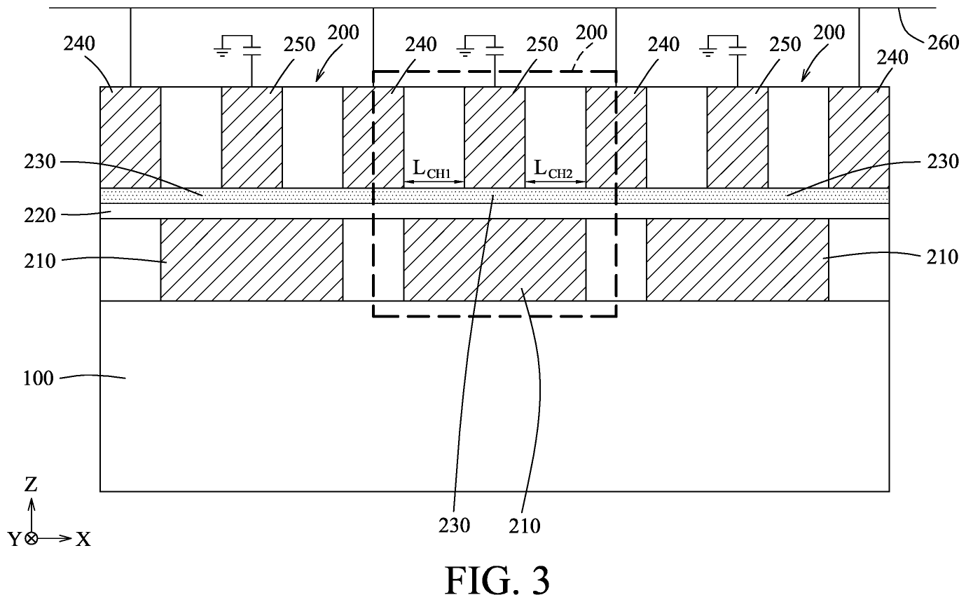

FIG. 3 illustrates a third embodiment of a memory device according to this disclosure. Similar to the second embodiment, the transistor 200 of each of the memory cells of the memory device of the third embodiment includes a gate electrode 210 formed on the substrate 100, a gate dielectric layer 220 formed over the gate electrode 210 in the Z-axis direction, a channel feature 230 formed over the gate dielectric layer 220 in the Z-axis direction, and a source electrode 250 formed over the channel feature 230 in the Z-axis direction, and the channel features 230 of the transistors 200 that are arranged or aligned in the X-axis direction are connected together, namely, formed in one piece (i.e., the channel layer common to the transistors 200 that are arranged or aligned in the X-axis direction is continuous). The third embodiment differs from the second embodiment in that each transistor 200 in the third embodiment includes two drain electrodes 240 that are disposed at opposite sides of the source electrode 250 in the X-axis direction (i.e., the source electrode 250 is disposed between the drain electrodes 240). For ease of explanation, one of the drain electrodes 240 that is disposed at a first side (e.g., the left side in FIG. 3) of the source electrode 250 is referred to as a first drain electrode 240, and the other one of the drain electrodes 240 that is disposed at a second side (which is opposite to the first side, e.g., the right side in FIG. 3) of the source electrode 250 is referred to as a second drain electrode 240. For each of the transistors 200, the channel feature 230 extends from the first drain electrode 240 to the second drain electrode 240, and has a first channel portion extending between and interconnecting the first drain electrode 240 and the source electrode 250 (i.e., a portion that extends from a right edge of the first drain electrode 240 to a left edge of the source electrode 250 in FIG. 3), and a second channel portion extending between and interconnecting the second drain electrode 240 and the source electrode 250 (i.e., a portion that extends from a right edge of the source electrode 250 to a left edge of the second drain electrode 240 in FIG. 3). A length of the first channel portion in the X-axis direction, which is equal to a distance between the first drain electrode 240 and the source electrode 250, is defined as a first channel length (L_{CH1}), and a length of the second channel portion in the X-axis direction, which is equal to a distance between the second drain electrode 240 and the source electrode 250, is defined as a second channel length (L_{CH2}). The gate electrode 210 overlaps both of the first channel portion and the second channel portion in the Z-axis direction. To be specific, the overlap between the gate electrode 210 and the first channel portion has a length in the X-axis direction (referred to as a first gate-channel overlapping length) that ranges from about two-thirds of the first channel length (i.e., 2L_{CH1}/3) to the entire first channel length, and the overlap between the gate electrode 210 and the second channel portion has a length in the X-axis direction (referred to as a second gate-channel overlapping length) that ranges from about two-thirds of the second channel length (i.e., 2LC_{H2}/3) to the entire second channel length. If the first gate-channel overlapping length is smaller than two-thirds of the first channel length or the second gate-channel overlapping length is smaller than two-thirds of the second channel length, the gate electrode 210 may have insufficient control over conductivity of the first channel portion or the second channel portion, which may make an off-state current of the transistor 200 increase. As a result, the transistors 200 in the third embodiment have two channels, one of which (referred to as a first channel) has the first channel length (L_{CH1}), and the other one of which (referred to as a second channel) has the second channel length (L_{CH2}). In view of the presence of the two channels, the transistors 200 of the third embodiment may, without increasing a size thereof, have a relatively large on-state current in comparison to the second embodiment. In the illustrative embodiment, the first channel length and the second channel length are configured to be the same (i.e., L_{CH1}=L_{CH2}), but this disclosure is not limited in this respect.

In the third embodiment, for two transistors 200 that are adjacent in the X-axis direction, the second drain electrode 240 of one transistor 200 and the first drain electrode 240 of the other transistor 200, which is disposed at the second side of said one transistor 200, are integrally formed together (i.e., formed in one piece). In other words, two transistors 200 that are adjacent in the X-axis direction have a common drain electrode 240. Furthermore, when the channel layer is made of a normally conducting material (i.e., conducting between the source electrode 250 and the drain electrodes 240 when no voltage is applied to the gate electrode 210), such as IGZO, ZnO, In₂O₃, or SnO₂ for n-type channels, or NiO, Cu₂O, CuAlO₂, CuGaO₂, CuInO₂, SrCu₂O₂, or SnO for p-type channels, the transistors 200 of the third embodiment may have a relatively smaller cell-to-cell leakage current in comparison to the second embodiment because conductivity of each portion of the channel layer disposed between one source electrode 250 and one drain electrode 240 that are adjacent in the X-axis direction is controlled by one gate electrode 210. During the operation of the memory device, for the transistors 200 that are electrically connected to the same bit line 260, only the gate electrode 210 of a selected one of the transistors 200 (selected to be turned on for read or write operation on the corresponding memory cell) is provided with an on-state voltage to make the portions of the channel layer that are disposed between the drain electrodes 240 and the source electrode 250 of the selected transistor 200 conduct, and the gate electrodes 210 of the other transistors 200 are provided with an off-state voltage to make the corresponding portions of the channel layer non-conducting, so the cell-to-cell leakage current, which is a part of an off-state current of the transistor 200, can be minimized.

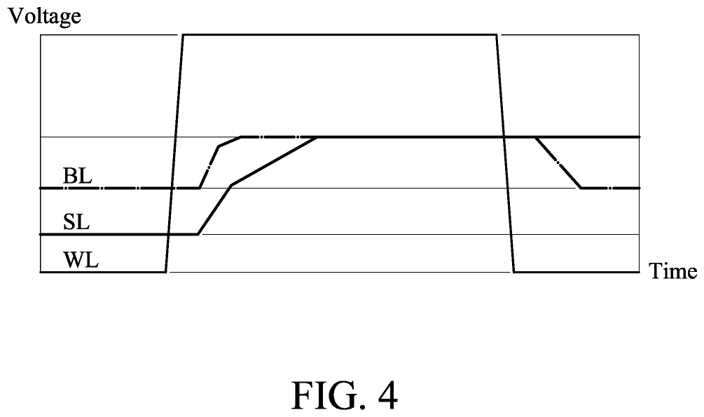

FIG. 4 illustrates an exemplary waveform diagram of a write operation to be performed on a memory cell in accordance with some embodiments. Further referring to FIG. 3, a curve “BL” in FIG. 4 represents a waveform of a bit-line voltage to be applied to the drain electrode 240 through the bit line 260, a curve “SL” in FIG. 4 represents a waveform of a voltage at the source electrode 250 (see FIG. 3), and a curve “WL” in FIG. 4 represents a waveform of a word-line voltage to be applied to the gate electrode 210. When the word-line voltage goes high, the transistor 200 is turned on to conduct, so a current flows into the storage capacitor through the transistor 200, making the voltage at the source electrode 250 gradually approach the bit-line voltage that represents a bit of data to be written into the memory cell. Then, the word-line voltage goes low to turn off the transistor 200 to prevent a current leaking out of the storage capacitor, so as to maintain the voltage at the source electrode 250 (i.e., keeping the data stored in the memory cell).

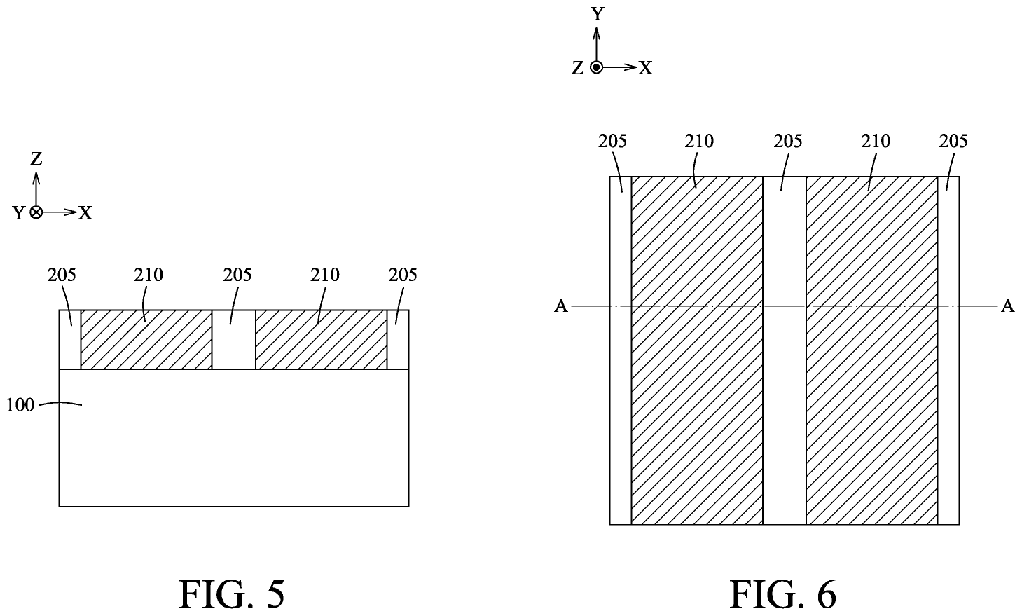

FIGS. 5 through 19 illustrate an exemplary process for fabricating the third embodiment of the memory device according to this disclosure.

Referring to FIGS. 5 and 6 where FIG. 5 illustrates a sectional view taken along line A-A in FIG. 6, a plurality of gate electrodes 210 are formed on a substrate 100. In some embodiments, the gate electrodes 210 are formed by depositing a first dielectric layer 205 over the substrate 100, etching the first dielectric layer 205 to form a plurality of trenches that extend in a Y-axis direction and that are arranged in the X-axis direction, and depositing a metal layer to form the gate electrodes 210 in the trenches. In some embodiments, a chemical-mechanical planarization (CMP) process may be performed after the deposition of the metal layer for forming the gate electrodes 210. The X-axis direction, the Y-axis direction and the Z-axis direction are transverse or perpendicular to each other. As a result, the gate electrodes 210 extend in the Y-axis direction and are isolated by the first dielectric layer 205 from each other in the X-axis direction.

The substrate 100 may be a bulk semiconductor substrate or a semiconductor-on-insulator (SOI) substrate, which may be doped (e.g., with a p-type or an n-type dopant) or undoped. In some embodiments, an SOI substrate includes a layer of a semiconductor material formed on an insulator layer. The insulator layer may be a buried oxide (BOX) layer, a silicon oxide layer or any other suitable layer. The insulator layer may be provided on a suitable substrate, such as silicon, glass or the like. The substrate 100 may be made of a suitable semiconductor material, such as silicon or the like. In some embodiments, the substrate 100 is a silicon wafer; and in other embodiments, the substrate 100 is made of a compound semiconductor such as silicon carbide, gallium arsenide, indium arsenide, indium phosphide or other suitable materials. In still other embodiments, the substrate 100 is made of an alloy semiconductor such as GaAsP, AlInAs, AlGaAs, GaInAs, GaInP, GaInAsP or other suitable materials.

In some embodiments, the substrate 100 includes various p-type doped regions and/or n-type doped regions, such as p-type wells, n-type wells, p-type source/drain features and/or n-type source/drain features, formed by a suitable process such as ion implantation, thermal diffusion, a combination thereof, or the like. In some embodiments, the substrate 100 may include other functional elements such as resistors, capacitors, diodes, transistors, and/or the like. The transistors are, for example, field effect transistors (FETs), such as planar FETs and/or 3D FETs (e.g., fin field effect transistors (FinFETs)). The substrate 100 may include lateral isolation features (e.g., shallow trench isolation (STI)) configured to separate various functional elements formed on and/or in the substrate 100.

In some embodiments, the first dielectric layer 205 may include, for example, silicon oxide, silicon nitride, silicon oxynitride, fluoride-doped silicate glass (FSG), a low-k dielectric material (i.e., a dielectric material that has a dielectric constant smaller than that of silicon dioxide), other suitable materials, or a combination thereof. In some embodiments, the first dielectric layer 205 may be formed using, for example, chemical vapor deposition (CVD), plasma enhanced chemical vapor deposition (PECVD), physical vapor deposition (PVD), atomic layer deposition (ALD), other suitable techniques, or a combination thereof. In some embodiments, the first dielectric layer 205 may be etched using, for example, wet etching, dry etching, other suitable techniques, or a combination thereof.

In some embodiments, the gate electrodes 210 may include, for example, TaN, TiN, W, Al, polysilicon, other suitable materials, or a combination thereof, and may be formed using, for example, CVD, PECVD, PVD, ALD, other suitable techniques, or any combination thereof.

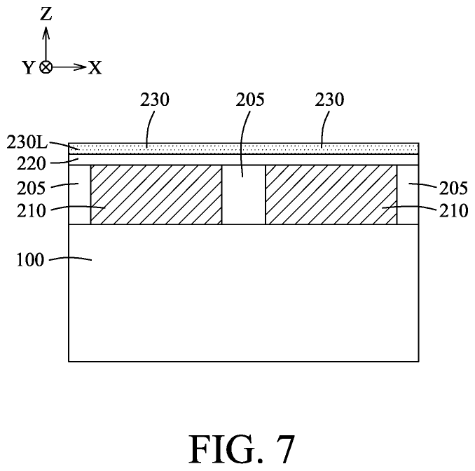

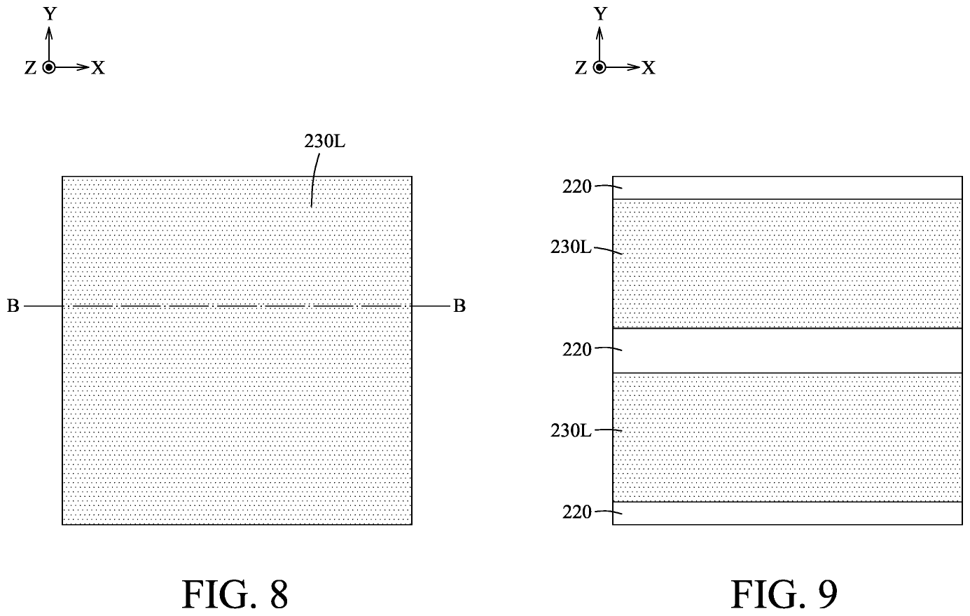

Referring to FIGS. 7 and 8 where FIG. 7 illustrates a sectional view taken along line B-B in FIG. 8, after the formation of the gate electrodes 210, a gate dielectric layer 220 is formed on the gate electrodes 210 and the first dielectric layer 205, and a channel layer 230L is formed on the gate dielectric layer 220. The channel layer 230L includes a plurality of channel features 230 that are formed in one piece and that respectively overlap the gate electrodes 210 in the Z-axis direction. In some embodiments, the gate dielectric layer 220 may include, for example, HfO₂, SiO₂, Al₂O₃, SiON, other suitable materials, or a combination thereof, and may be formed using, for example, CVD, PECVD, PVD, other suitable techniques, or any combination thereof. In some embodiments where the channel layer 230L is to form n-type channels, the channel layer 230L may include, for example, IGZO, ZnO, In₂O₃, SnO₂, other suitable materials, or a combination thereof. In some embodiments where the channel layer 230L is to form p-type channels, the channel layer 230L may include, for example, NiO, Cu₂O, CuAlO₂, CuGaO₂, CuInO₂, SrCu₂O₂, SnO, other suitable materials, or a combination thereof. The channel layer 230L may be formed using, for example, CVD, PECVD, PVD, ALD, other suitable techniques, or a combination thereof. Then, referring to FIG. 9, the channel layer 230L is etched to divide the channel layer 230L into multiple channel layer segments (also denoted as “230L” hereinafter) arranged and spaced apart from each other in the Y-axis direction, so the gate dielectric layer 220 is partly exposed between the channel layer segments 230L. In some embodiments, the channel layer 230L may be etched using, for example, dry etching, reactive ion etching (RIE), atomic layer etching (ALE), other suitable techniques, or a combination thereof.

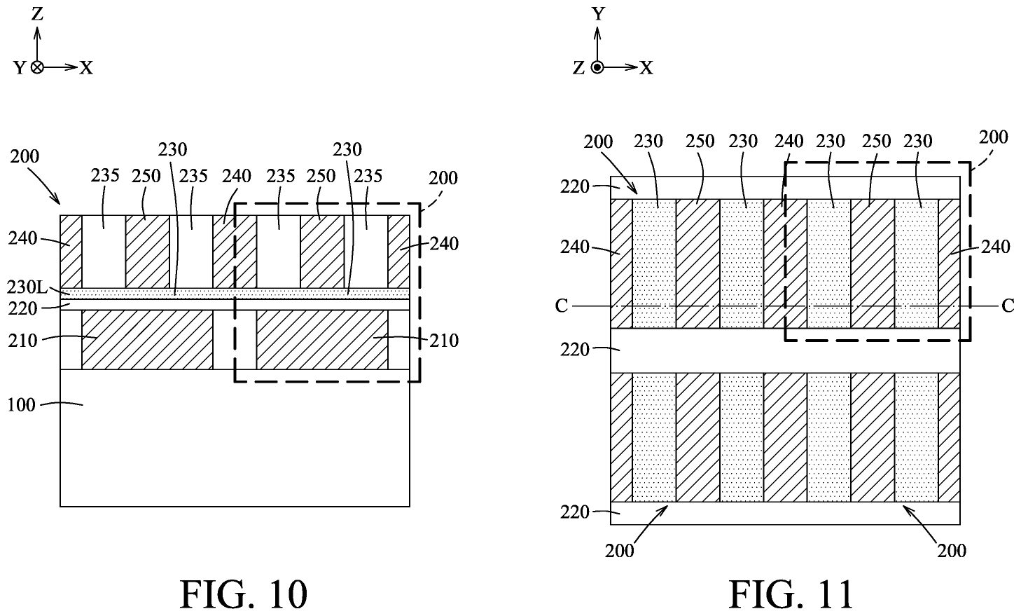

Referring to FIGS. 10 and 11 where FIG. 10 illustrates a sectional view taken along line C-C in FIG. 11, after the channel layer 230L is etched into the channel layer segments 230L, a plurality of drain electrodes 240 and a plurality of source electrodes 250 are formed on each of the channel layer segments 230L to be alternately arranged in the X-axis direction. In this step, a second dielectric layer 235 is first formed on the channel layer segments 230L and the exposed portion of the gate dielectric layer 220. It is noted that the second dielectric layer 235 is omitted from FIG. 11 in order to show the main structure of the memory device clearly. Then, the second dielectric layer 235 is etched to form a plurality of trenches therein, and a metal layer is deposited to form the drain electrodes 240 and the source electrodes 250 in the trenches that are formed in the second dielectric layer 235. In some embodiments, a CMP process may be performed after the deposition of the metal layer for forming the drain electrodes 240 and the source electrodes 250. In some embodiments, the second dielectric layer 235 may include, for example, silicon oxide, silicon nitride, silicon oxynitride, FSG, a low-k dielectric material, other suitable materials, or a combination thereof, and may be formed using, for example, CVD, PECVD, PVD, ALD, other suitable techniques, or a combination thereof. In some embodiments, the second dielectric layer 235 may be etched using, for example, wet etching, dry etching, other suitable techniques, or a combination thereof. In some embodiments, the drain electrodes 240 and the source electrodes 250 may include, for example, TaN, TiN, W, Al, polysilicon, Ru, Co, Cu, other suitable materials, or a combination thereof.

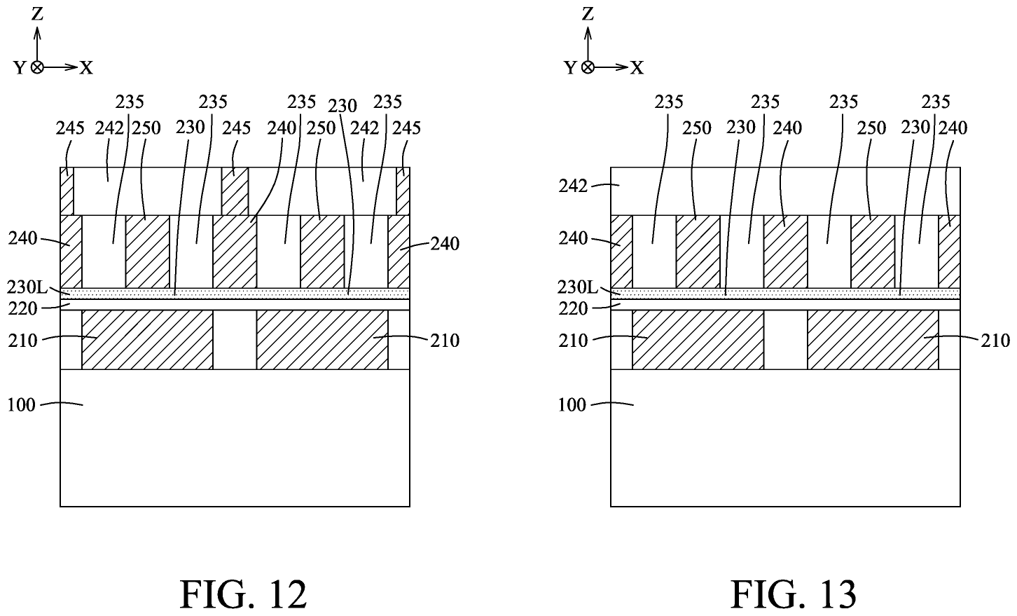

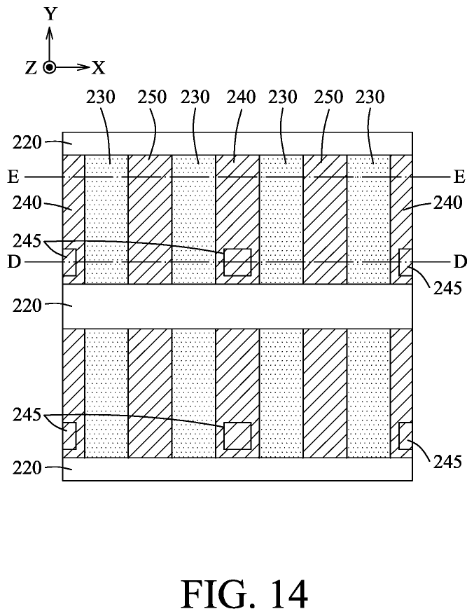

Referring to FIGS. 12, 13 and 14, where FIG. 12 illustrates a sectional view taken along line D-D in FIG. 14, and FIG. 13 illustrates a sectional view taken along line E-E in FIG. 14, a third dielectric layer 242 is formed on the second dielectric layer 235, the drain electrodes 240 and the source electrodes 250; the third dielectric layer 242 is then etched to form a plurality of via holes corresponding in position to the drain electrodes 240; and a metal layer is deposited to fill the via holes, so as to form a plurality of drain connection vias 245 that extend in the Z-axis direction and that are respectively connected to the drain electrodes 240. It is noted that the second dielectric layer 235 and the third dielectric layer 242 are omitted from FIG. 14 in order to show the main structure of the memory device clearly. In some embodiments, a CMP process may be performed after the deposition of the metal layer for forming the drain connection vias 245. In some embodiments, the third dielectric layer 242 may include, for example, silicon oxide, silicon nitride, silicon oxynitride, FSG, a low-k dielectric material, other suitable materials, or a combination thereof, and may be formed using, for example, CVD, PECVD, PVD, ALD, other suitable techniques, or a combination thereof. In some embodiments, the third dielectric layer 242 may be etched using, for example, wet etching, dry etching, other suitable techniques, or a combination thereof. In some embodiments, the drain connection vias 245 may include, for example, TaN, TiN, W, Al, polysilicon, Ru, Co, Cu, other suitable materials, or a combination thereof.

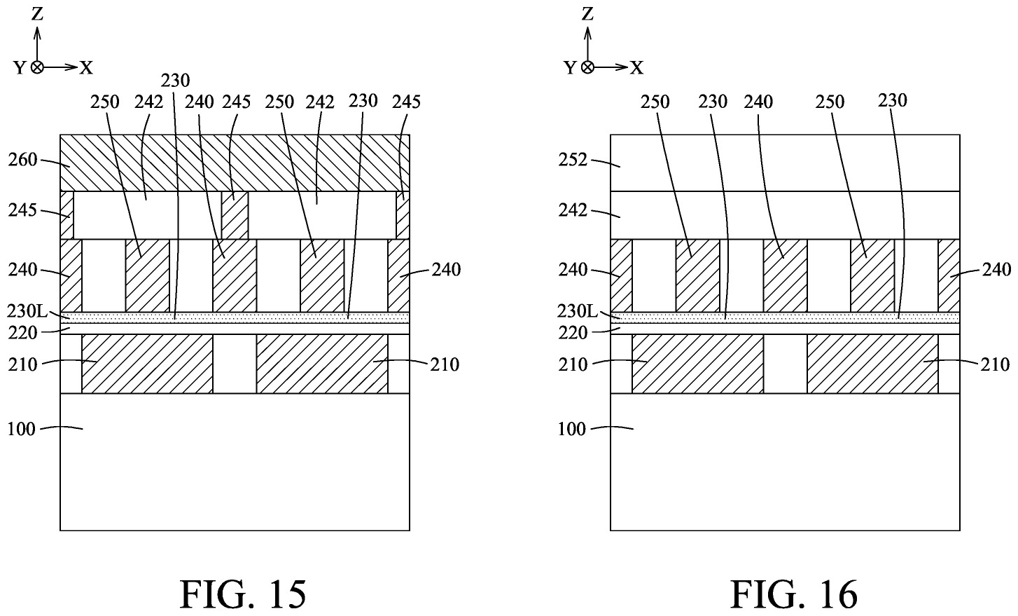

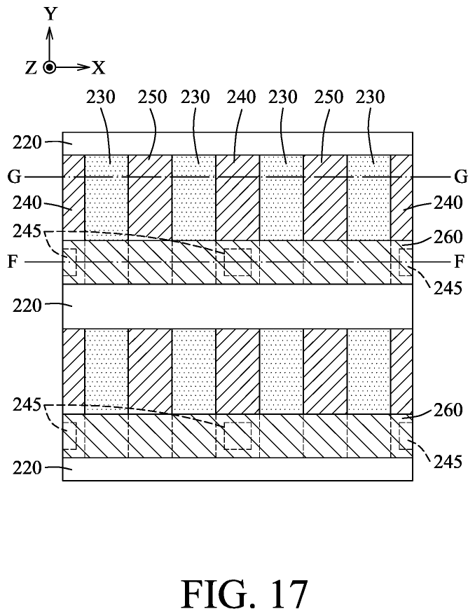

Referring to FIGS. 15, 16 and 17, where FIG. 15 illustrates a sectional view taken along line F-F in FIG. 17, and FIG. 16 illustrates a sectional view taken along line G-G in FIG. 17, a fourth dielectric layer 252 is formed on the third dielectric layer 242 and the drain connection vias 245; the fourth dielectric layer 252 is then etched to form a plurality of trenches therein. Each of the trenches extends in the X-axis direction and corresponds in position to some of the drain connection vias 245 that are arranged or aligned in the X-axis direction; as a result, the drain connection vias 245 are exposed in the trenches; and a metal layer is deposited to form the bit lines 260 respectively in the trenches. It is noted that the second dielectric layer 235, the third dielectric layer 242 and the fourth dielectric layer 252 are omitted from FIG. 17 in order to show the main structure of the memory device clearly. In some embodiments, a CMP process may be performed after the deposition of the metal layer for forming the bit lines 260. In some embodiments, the fourth dielectric layer 252 may include, for example, silicon oxide, silicon nitride, silicon oxynitride, FSG, a low-k dielectric material, other suitable materials, or a combination thereof, and may be formed using, for example, CVD, PECVD, PVD, ALD, other suitable techniques, or a combination thereof. In some embodiments, the fourth dielectric layer 252 may be etched using, for example, wet etching, dry etching, other suitable techniques, or a combination thereof. In some embodiments, the bit lines 260 may include, for example, TaN, TiN, W, Al, polysilicon, Ru, Co, Cu, other suitable materials, or a combination thereof. As a result, each bit line 260 electrically interconnects the corresponding drain electrodes 240 that are aligned in the X-axis direction through the corresponding drain election vias 245.

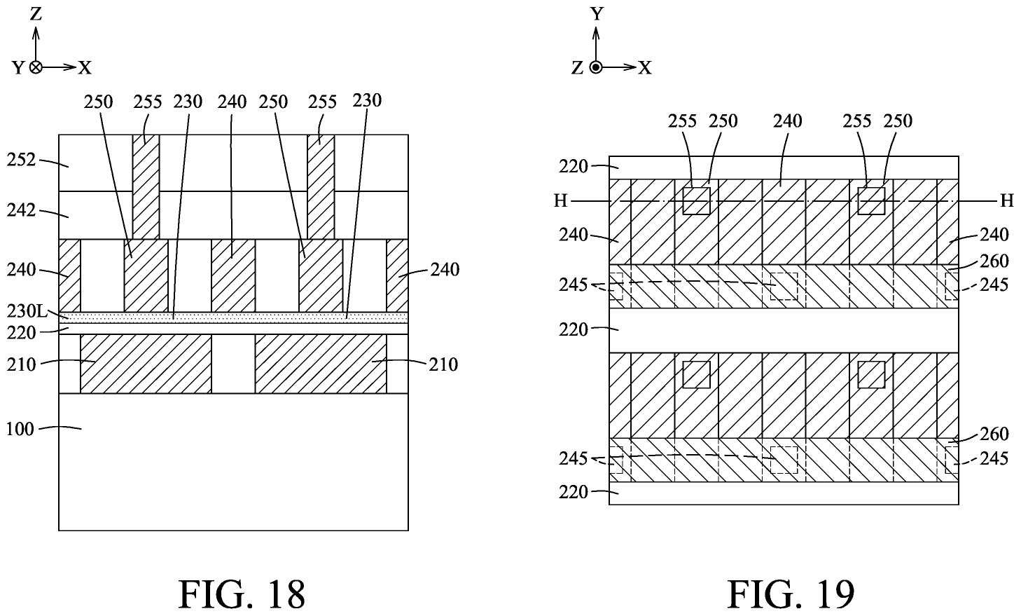

Referring to FIGS. 18 and 19 where FIG. 18 illustrates a sectional view taken along line H-H in FIG. 19, the fourth dielectric layer 252 and the third dielectric layer 242 are etched to form a plurality of via holes corresponding in position to the source electrodes 250; and a metal layer is deposited to fill the via holes, so as to form a plurality of source connection vias 255 that extend in the Z-axis direction and that are respectively connected to the source electrodes 250. It is noted that the second dielectric layer 235, the third dielectric layer 242 and the fourth dielectric layer 252 are omitted from FIG. 19 in order to show the main structure of the memory device clearly. In some embodiments, a CMP process may be performed after the deposition of the metal layer for forming the source connection vias 255. In some embodiments, the source connection vi as 255 may include, for example, TaN, TiN, W, Al, polysilicon, Ru, Co, Cu, other suitable materials, or a combination thereof. Each of the source connection vias 255 are to be connected to the storage capacitor of the corresponding memory cell, which would be formed in the subsequent process.

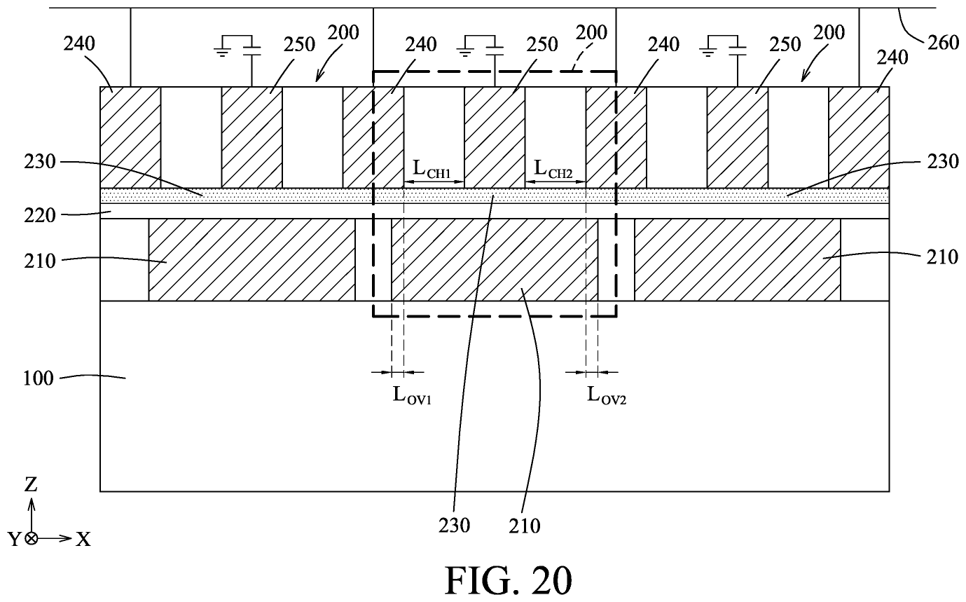

FIG. 20 illustrates a fourth embodiment of a memory device according to this disclosure. The fourth embodiment is similar to the third embodiment, but differs from the third embodiment in that, for each of the memory cells in the fourth embodiment, the gate electrode 210 of the transistor 200 overlaps both of the first drain electrode 240 and the second drain electrode 240 in the Z-axis direction with an overlapping length of L_{OV1} with respect to the first drain electrode 240 in the X-axis direction and an overlapping length of L_{OV2} with respect to the second drain electrode 240 in the X-axis direction. In comparison with the third embodiment, the overlaps between the gate electrode 210 and the drain electrodes 240 make the gate electrode 210 in the fourth embodiment have a greater area to control the conductivity of the channel feature 230, so as to reduce the off-state current of the transistor 200 when the gate electrode 210 is provided with the off-state voltage.

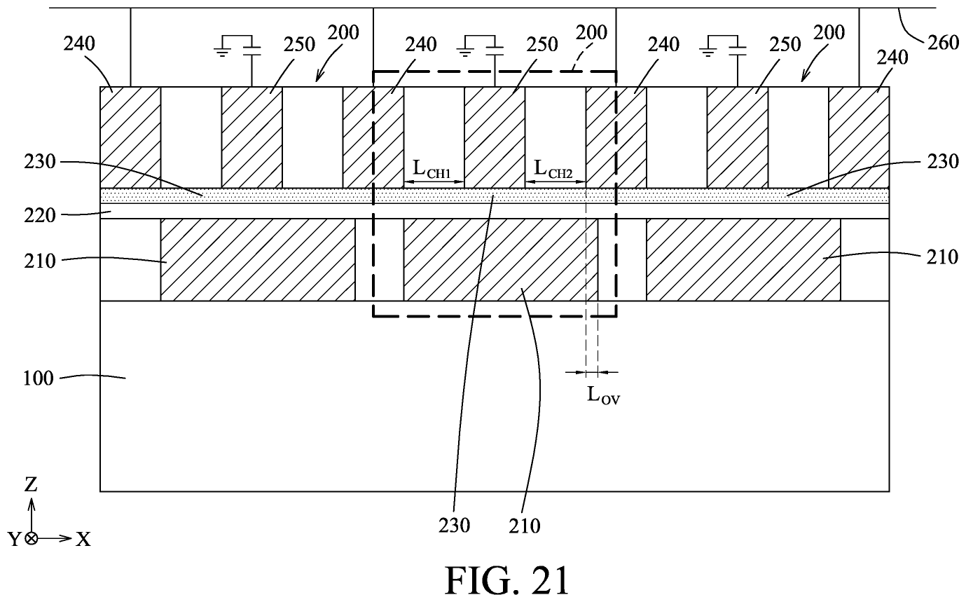

FIG. 21 illustrates a fifth embodiment of a memory device according to this disclosure. The fifth embodiment is similar to the third embodiment, but differs from the third embodiment in that, for each of the memory cells in the fifth embodiment, the gate electrode 210 of the transistor 200 overlaps one of the drain electrodes 240 in the Z-axis direction with an overlapping length of Loy in the X-axis direction. In comparison with the third embodiment, the overlap between the gate electrode 210 and said one of the drain electrodes 240 makes the gate electrode 210 in the fifth embodiment have a greater area to control the conductivity of the channel feature 230, so as to reduce the off-state current of the transistor 200 when the gate electrode 210 is provided with the off-state voltage.

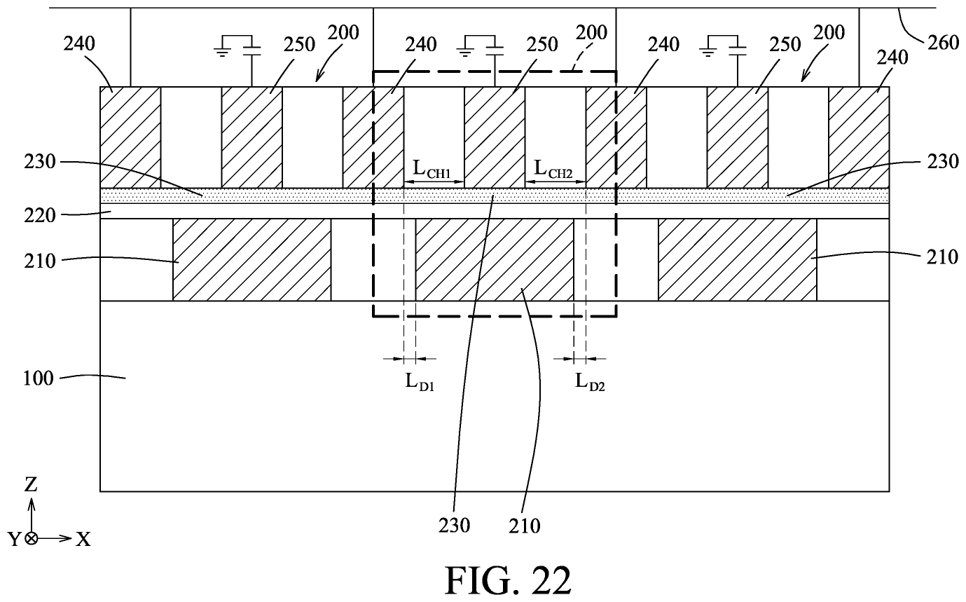

FIG. 22 illustrates a sixth embodiment of a memory device according to this disclosure. The sixth embodiment is similar to the third embodiment, but differs from the third embodiment in that, for each of the memory cells in the sixth embodiment, the gate electrode 210 of the transistor 200 is non-overlapping with both of the first drain electrode 240 and the second drain electrode 240 in the Z-axis direction and is spaced apart from the first drain electrode 240 and the second drain electrode 240 in the X-axis direction respectively by a spacing of L_{D1} and a spacing of L_{D2}, which means that, as exemplified in FIG. 22, the gate electrode 210 is separated from a plane which is where a right edge of the first drain electrode 240 lies and which is perpendicular to the X-axis direction by a distance of L_{D1}, and is separated from a plane which is where a left edge of the second drain electrode 240 lies and which is perpendicular to the X-axis direction by a distance of L_{D2}. In comparison with the third embodiment, because the sixth embodiment has a greater spacing between the gate electrode 210 and each of the drain electrodes 240, capacitances between the gate electrode 210 and the drain electrodes 240 are reduced, so an operation speed of the transistor 200 is enhanced, resulting in a faster read/write operation of the memory cell. In some embodiment, the spacing between the first drain electrode 240 and the gate electrode 210 in the X-axis direction ranges from zero to about one-third of the first channel length (i.e., 0≤L_{D1}≤L_{CH1}/3), and the spacing between the second drain electrode 240 and the gate electrode 210 in the X-axis direction ranges from zero to about one-third of the second channel length (i.e., 0≤L_{D2}≤L_{CH2}/3).

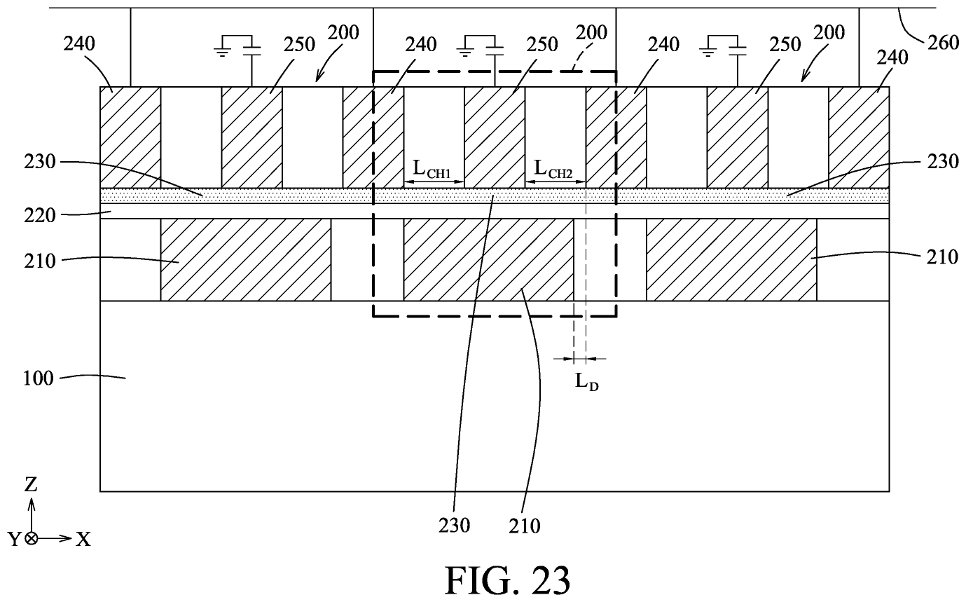

FIG. 23 illustrates a seventh embodiment of a memory device according to this disclosure. The seventh embodiment is similar to the third embodiment, but differs from the third embodiment in that, for each of the memory cells in the seventh embodiment, the gate electrode 210 of the transistor 200 is non-overlapping with one of the drain electrodes 240 in the Z-axis direction, and is spaced apart in the X-axis direction from said one of the drain electrodes 240 by a spacing of LD, which means that, as exemplified in FIG. 23, the gate electrode 210 is separated from a plane which is where an edge (the one that is proximate to the gate electrode 210) of said one of the drain electrodes 240 lies and which is perpendicular to the X-axis direction by a distance of LD. In comparison with the third embodiment, because the seventh embodiment has a greater distance between the gate electrode 210 and said one of the drain electrodes 240, capacitance between the gate electrode 210 and said drain electrode 240 is reduced, so an operation speed of the transistor 200 is enhanced, resulting in a faster read/write operation of the memory cell.

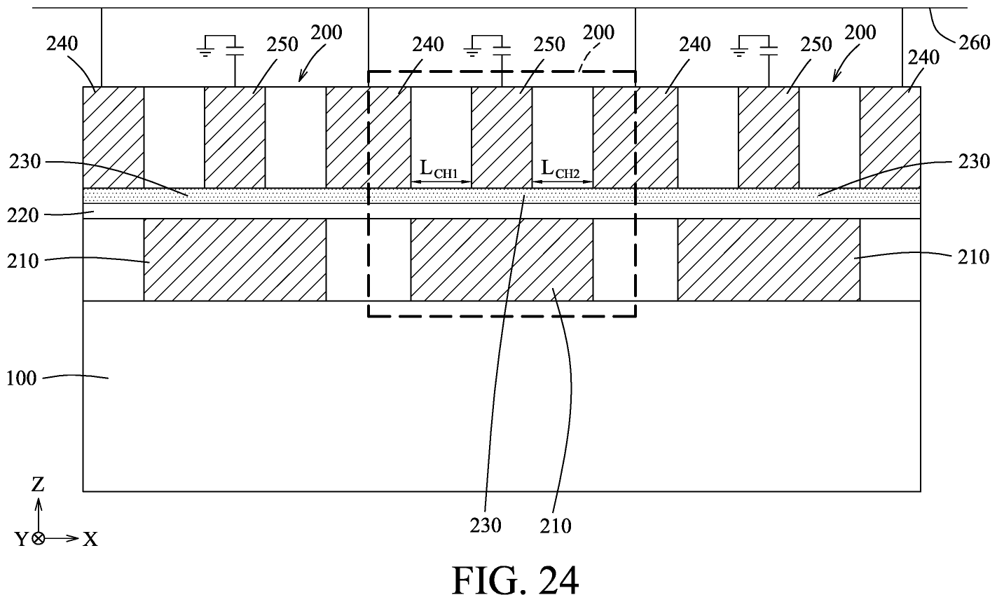

FIG. 24 illustrates an eighth embodiment of a memory device according to this disclosure. The eighth embodiment is similar to the third embodiment, but differs from the third embodiment in that the drain electrodes 240 in the eighth embodiment are longer in the X-axis direction than the source electrodes 250. The greater length of the drain electrodes 240 leads to smaller resistances for the drain electrodes 240, resulting in a faster read/write operation of the memory cells.

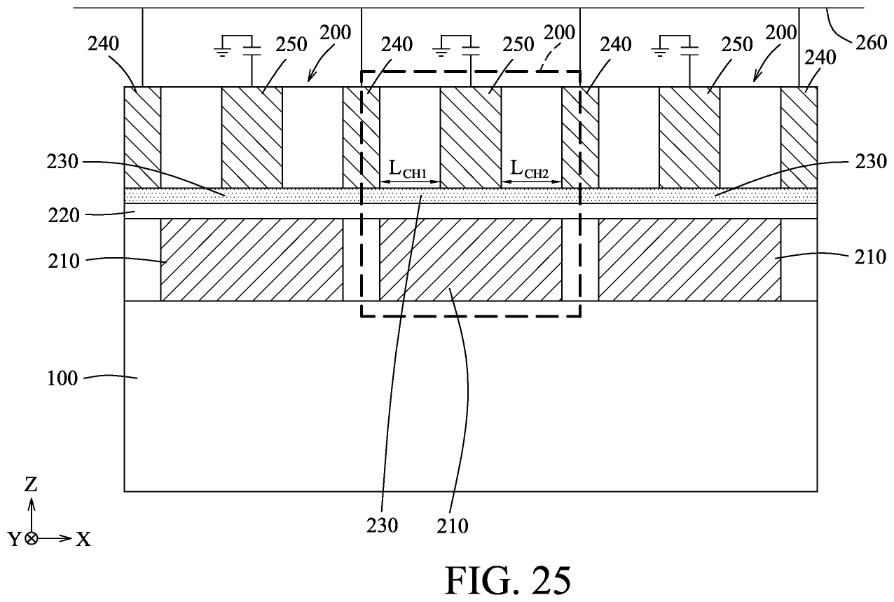

FIG. 25 illustrates a ninth embodiment of a memory device according to this disclosure. The ninth embodiment is similar to the third embodiment, but differs from the third embodiment in that the drain electrodes 240 are shorter in the X-axis direction than the source electrodes 250. The smaller length of the drain electrodes 240 leads to smaller capacitances between the gate electrodes 210 and the drain electrodes 240, resulting in less delay in terms of switching of the transistors 200.

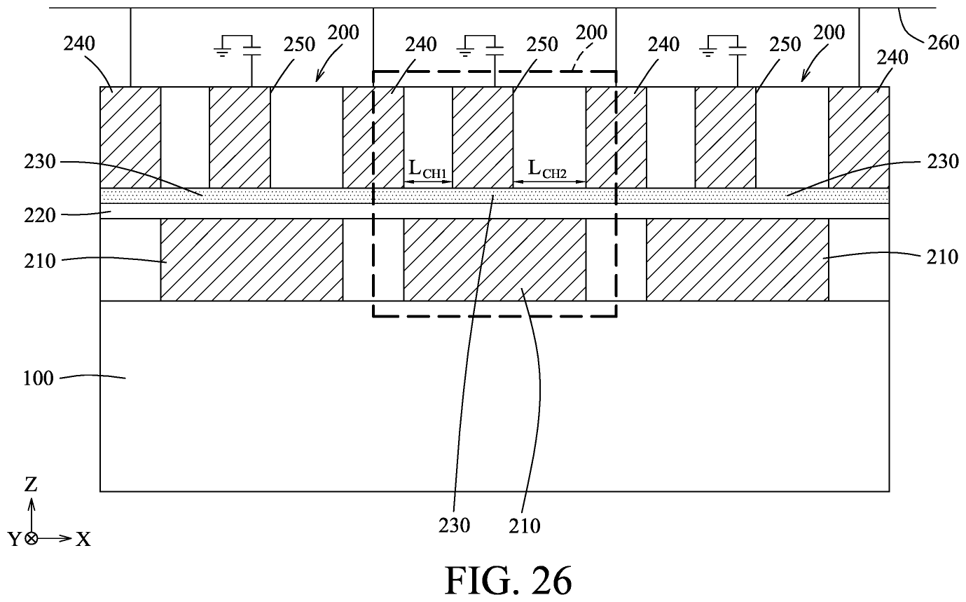

FIG. 26 illustrates a tenth embodiment of a memory device according to this disclosure. The tenth embodiment is similar to the third embodiment, but differs from the third embodiment in that, for each of the transistors 200, the first channel length (L_{CH1}) and the second channel length (L_{CH2}) are different. In view of the presence of two channels, the transistors 200 of the tenth embodiment may have a relatively large on-state current in comparison to the second embodiment.

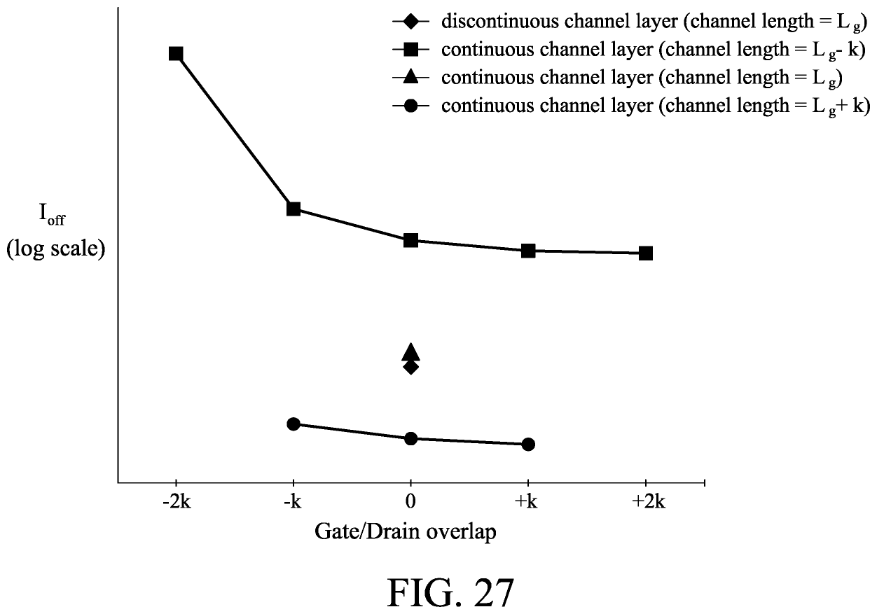

FIG. 27 is a plot illustrating a comparison of off-state currents (Ioff) for different configurations of the transistor 200 that correspond to different embodiments, where Lg is a predetermined reference channel length, and k is a predetermined modification length, which is about Lg/6 in this plot. A positive value of Gate/Drain overlap refers to a length in the X-axis direction of an overlap in the Z-axis direction between the gate electrode 210 and each of the drain electrodes 240 in the fourth embodiment (i.e., L_{OV1} and L_{OV2} in FIG. 20 and L_{OV1}=L_{OV2}), and a negative value of Gate/Drain overlap refers to a length in the X-axis direction of a spacing between the gate electrode 210 and each of the drain electrodes 240 when viewed from the Z-axis direction in the sixth embodiment (i.e., L_{D1} and L_{D2} in FIG. 22 and L_{D1}=L_{D2}).

In FIG. 27, the data point for “discontinuous channel layer” corresponds to the first embodiment (see FIG. 1), where L_{CH}=Lg; the data point for “continuous channel layer (channel length=Lg)” with the gate/drain overlap equaling zero corresponds to the third embodiment (see FIG. 3), where L_{CH1}=L_{CH2}=Lg; the data point of a curve of “continuous channel layer (channel length=Lg−k)” with the gate/drain overlap equaling zero corresponds to the third embodiment (see FIG. 3), where L_{CH1}=L_{CH2}=Lg−k; and the data point of a curve of “continuous channel layer (channel length=Lg+k)” with the gate/drain overlap equaling zero corresponds to the third embodiment (see FIG. 3), where L_{CH1}=L_{CH2}=Lg+k. These four data points, which correspond to zero gate/drain overlap, illustrate that the channel length dominates the off-state current, meaning that the greater the channel length, the smaller the off-state current, and also illustrate that the structure of the channel layer (discontinuous or continuous) does not have significant influence on the off-state current.

For the curve of “continuous channel layer (channel length=Lg−k)”, the rightmost two data points that correspond to positive gate/drain overlaps (i.e., +k and +2k) correspond to the fourth embodiment (see FIG. 20), where L_{CH1}=L_{CH2}=Lg−k and L_{OV1}=L_{OV2}=k or 2k; and the leftmost two data points that correspond to negative gate/drain overlaps (i.e., −k and −2k) correspond to the sixth embodiment (see FIG. 22), where L_{CH1}=L_{CH2}=Lg−k and L_{D1}=L_{D2}=k or 2k. For the leftmost two data points, since the gate electrode 210 is spaced apart from the drain electrodes 240 in the X-axis direction, the effective channel lengths (each being a length in the X-axis direction of an overlap in the Z-axis direction between the first/second channel portion and the gate electrode 210) would be calculated as being L_{CH1}−L_{D1} and L_{CH2}−L_{D2}, respectively, each being shorter than the corresponding channel length L_{CH1} or L_{CH2} that is defined as a distance in the X-axis direction between the gate electrode 210 and the corresponding one of the drain electrodes 240.

For the curve of “continuous channel layer (channel length=Lg+k)”, the right data point corresponding to a positive gate/drain overlap (i.e., +k) corresponds to the fourth embodiment (see FIG. 20), where L_{CH1}=L_{CH2}=Lg+k and L_{OV1}=L_{OV2}=k; and the left data point corresponding to a negative gate/drain overlap (i.e., −k) corresponds to the sixth embodiment (see FIG. 22), where L_{CH1}=L_{CH2}=Lg+k and L_{D1}=L_{D2}=k. For the left data point, since the gate electrode 210 is spaced apart from the drain electrodes 240 in the X-axis direction, the effective channel lengths (each being a length in the X-axis direction of a part of the first/second channel portion that overlaps the gate electrode 210 in the Z-axis direction) would be calculated as being L_{CH1}−L_{D1} and L_{CH2}−L_{D2}, respectively, each being shorter than the corresponding channel length L_{CH1} or L_{CH2} that is defined as a distance in the X-axis direction between the gate electrode 210 and the corresponding one of the drain electrodes 240.

As a result, based on the four data points that correspond to zero gate/drain overlap, based on the curve of “continuous channel layer (channel length=Lg−k)” and based on the curve of “continuous channel layer (channel length=Lg+k)”, it can be derived that the effective channel lengths dominate the off-state current of the transistors 200 of the memory cells, and the greater the effective channel length, the smaller the off-state current. On the other hand, the structure of the channel layer (discontinuous or continuous) and the overlaps (i.e., L_{OV1} and L_{OV2} in FIG. 20) in the X-axis direction between the gate electrode 210 and the drain electrodes 240 do not have significant influence on the off-state current.

In summary, in some embodiments of the memory device according to the disclosure, the transistor 200 has two drain electrodes 240 disposed at opposite sides of the source electrode 250, so as to form two channels therein and thus have a relatively large on-state current. Furthermore, in some embodiments, two adjacent transistors 200 have a common drain electrode 240, so each portion of the channel layer disposed between one source electrode 250 and one drain electrode 240 is controlled by one gate electrode 210, and the cell-to-cell leakage current can thus be minimized.

In accordance with some embodiments, a memory device is provided to include a first memory cell that includes a first transistor and a first capacitor electrically connected to the first transistor. The first transistor includes a gate electrode formed on a semiconductor substrate, a gate dielectric disposed over the gate electrode in a Z-axis direction, a channel feature disposed over the gate dielectric and overlapping the gate electrode in the Z-axis direction, a source electrode disposed over the channel feature in the Z-axis direction and electrically connected to the first capacitor, a first drain electrode disposed over the channel feature in the Z-axis direction, and a second drain electrode disposed over the channel feature in the Z-axis direction. The first drain electrode is disposed at a first side of the source electrode in an X-axis direction that is transverse to the Z-axis direction, the second drain electrode is disposed at a second side of the source electrode in the X-axis direction, and the second side is opposite to the first side. The channel feature has a first channel portion extending between and interconnecting the first drain electrode and the source electrode, and a second channel portion extending between and interconnecting the second drain electrode and the source electrode, and the gate electrode overlaps both of the first channel portion and the second channel portion of the channel feature in the Z-axis direction.

In accordance with some embodiments, the memory device further includes a second memory cell. The second memory cell includes a second transistor and a second capacitor electrically connected to the second transistor. The second transistor includes a gate electrode formed on the semiconductor substrate, a gate dielectric disposed over the gate electrode in the Z-axis direction, a channel feature disposed over the gate dielectric and overlapping the gate electrode in the Z-axis direction, a source electrode disposed over the channel feature in the Z-axis direction and electrically connected to the second capacitor, a first drain electrode disposed over the channel feature in the Z-axis direction, and a second drain electrode disposed over the channel feature in the Z-axis direction. For the second transistor, the first drain electrode is disposed at the first side of the source electrode in the X-axis direction, the second drain electrode is disposed at the second side of the source electrode in the X-axis direction. For the second transistor, the channel feature has a first channel portion extending between and interconnecting the first drain electrode and the source electrode, and a second channel portion extending between and interconnecting the second drain electrode and the source electrode, and the gate electrode overlaps both of the first channel portion and the second channel portion of the channel feature in the Z-axis direction. The channel features of the first transistor and the second transistor are formed in one piece.

In accordance with some embodiments, the second drain electrode of the first transistor and the first drain electrode of the second transistor are formed in one piece.

In accordance with some embodiments, for the first transistor, the gate electrode overlaps one or both of the first drain electrode and the second drain electrode in the Z-axis direction.

In accordance with some embodiments, for the first transistor, the gate electrode is spaced apart from one or both of the first drain electrode and the second drain electrode in the X-axis direction.

In accordance with some embodiments, for the first transistor, each of the first drain electrode and the second drain electrode has a length in the X-axis direction greater than that of the source electrode.

In accordance with some embodiments, for the first transistor, each of the first drain electrode and the second drain electrode has a length in the X-axis direction smaller than that of the source electrode.

In accordance with some embodiments, for the first transistor, an overlap between the gate electrode and the first channel portion in the Z-axis direction has a length in the X-axis direction greater than or equal to two-thirds of a length of the first channel portion in the X-axis direction, and an overlap between the gate electrode and the second channel portion in the Z-axis direction has a length in the X-axis direction greater than or equal to two-thirds of a length of the second channel portion in the X-axis direction.

In accordance with some embodiments, the channel feature of each of the first transistor and the second transistor includes at least one of IGZO, ZnO, In₂O₃, SnO₂, NiO, Cu₂O, CuAlO₂, CuGaO₂, CuInO₂, SrCu₂O₂, or SnO.

In accordance with some embodiments, the memory device further includes a bit line that electrically interconnects the first drain electrodes and the second drain electrodes of the first transistor and the second transistor.

In accordance with some embodiments, a memory device is provided to include a first transistor and a first capacitor. The first transistor includes a gate electrode, a first drain electrode, a second drain electrode, a source electrode, a channel feature and a gate dielectric layer. The gate electrode is formed on a semiconductor substrate. The first drain electrode, the second drain electrode and the source electrode are formed in one layer, are arranged in an X-axis direction, and are disposed above the gate electrode in a Z-axis direction that is transverse to the X-axis direction. The source electrode is disposed between the first drain electrode and the second drain electrode. The channel feature is disposed between the gate electrode and said one layer where the first drain electrode, the second drain electrode and the source electrode are formed, and extends from the first drain electrode to the second drain electrode. The gate dielectric layer is disposed between the gate electrode and the channel feature. The first capacitor is electrically connected to the source electrode of the first transistor. The channel feature has a first channel portion extending between and interconnecting the first drain electrode and the source electrode, and a second channel portion extending between and interconnecting the second drain electrode and the source electrode, and the gate electrode overlaps both of the first channel portion and the second channel portion of the channel feature.

In accordance with some embodiments, the memory device further includes a second transistor and a second capacitor. The second transistor includes a gate electrode, a first drain electrode, a second drain electrode, a source electrode, a channel feature and a gate dielectric layer. The gate electrode is formed on the semiconductor substrate. The first drain electrode, the second drain electrode and the source electrode are formed in said one layer, are arranged in the X-axis direction, and are disposed above the gate electrode. The source electrode of the second transistor is disposed between the first drain electrode of the second transistor and the second drain electrode of the second transistor. The channel feature is disposed between the gate electrode and said one layer, and extends from the first drain electrode to the second drain electrode. The gate dielectric layer is disposed between the gate electrode and the channel feature. The second capacitor is electrically connected to the source electrode of the second transistor. For the second transistor, the channel feature has a first channel portion extending between and interconnecting the first drain electrode and the source electrode, and a second channel portion extending between and interconnecting the second drain electrode and the source electrode, and the gate electrode overlaps both of the first channel portion and the second channel portion of the channel feature. The channel features of the first transistor and the second transistor are formed in one piece.

In accordance with some embodiments, the second drain electrode of the first transistor and the first drain electrode of the second transistor are formed in one piece.

In accordance with some embodiments, for the first transistor, a spacing between the gate electrode and the first drain electrode in the X-axis direction ranges from zero to one-third of a length of the first channel portion in the X-axis direction, and a spacing between the gate electrode and the second drain electrode in the X-axis direction ranges from zero to one-third of a length of the second channel portion in the X-axis direction.

In accordance with some embodiments, the channel feature of each of the first transistor and the second transistor includes at least one of IGZO, ZnO, In₂O₃, SnO₂, NiO, Cu₂O, CuAlO₂, CuGaO₂, CuInO₂, SrCu₂O₂, or SnO.

In accordance with some embodiments, a method for fabricating a memory device is provided. In one step, a plurality of gate electrodes that are arranged in an X-axis direction are formed on a semiconductor substrate. In one step, a gate dielectric layer is formed over the gate electrodes in a Z-axis direction that is transvers to the X-axis direction. In one step, a channel layer is formed over the gate dielectric layer in the Z-axis direction. The channel layer includes a plurality of channel features that are formed in one piece and that respectively overlap the gate electrodes in the Z-axis direction. In one step, a first drain electrode, a second drain electrode and a source electrode are formed over each of the channel features in the Z-axis direction. The first drain electrode, the second drain electrode and the source electrode are arranged in the X-axis direction with the source electrode being disposed between the first drain electrode and the second drain electrode. With respect to each of the channel features, a storage capacitor is formed to be electrically connected to the source electrode which is disposed over the channel feature.

In accordance with some embodiments, the channel features include a first channel feature and a second channel feature that are adjacent in the X-axis direction, and the second drain electrode formed on the first channel feature and the first drain electrode formed on the second channel feature are formed in one piece.

In accordance with some embodiments, each of the channel features includes a first channel portion extending from the first drain electrode formed on the channel feature to the source electrode formed on the channel feature, and a second channel portion extending from the second drain electrode formed on the channel feature to the source electrode formed on the channel feature. Each of the gate electrodes overlaps both of the first channel portion and the second channel portion of the respective one of the channel features in the Z-axis direction.

In accordance with some embodiments, for each of the channel features, an overlap between the first channel portion of the channel feature and the respective one of the gate electrodes has a length in the X-axis direction greater than or equal to two-thirds of a length of the first channel portion in the X-axis direction, and an overlap between the second channel portion of the channel feature and the respective one of the gate electrodes has a length in the X-axis direction greater than or equal to two-thirds of a length of the second channel portion in the X-axis direction.

In accordance with some embodiments, the channel layer includes at least one of IGZO, ZnO, In₂O₃, SnO₂, NiO, Cu₂O, CuAlO₂, CuGaO₂, CuInO₂, SrCu₂O₂, or SnO.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a first memory cell including a first transistor and a first capacitor electrically connected to the first transistor;
wherein the first transistor includes a gate electrode formed on a semiconductor substrate, a gate dielectric disposed over the gate electrode in a Z-axis direction, a channel feature disposed over the gate dielectric and overlapping the gate electrode in the Z-axis direction, a source electrode disposed over the channel feature in the Z-axis direction and electrically connected to the first capacitor, a first drain electrode disposed over the channel feature in the Z-axis direction, and a second drain electrode disposed over the channel feature in the Z-axis direction;
wherein the first drain electrode is disposed at a first side of the source electrode in an X-axis direction that is transverse to the Z-axis direction, the second drain electrode is disposed at a second side of the source electrode in the X-axis direction, and the second side is opposite to the first side;
wherein the channel feature has a first channel portion extending between and interconnecting the first drain electrode and the source electrode, and a second channel portion extending between and interconnecting the second drain electrode and the source electrode, and the gate electrode overlaps both of the first channel portion and the second channel portion of the channel feature in the Z-axis direction.

2. The memory device according to claim 1, further comprising:
a second memory cell including a second transistor and a second capacitor electrically connected to the second transistor;
wherein the second transistor includes a gate electrode formed on the semiconductor substrate, a gate dielectric disposed over the gate electrode in the Z-axis direction, a channel feature disposed over the gate dielectric and overlapping the gate electrode in the Z-axis direction, a source electrode disposed over the channel feature in the Z-axis direction and electrically connected to the second capacitor, a first drain electrode disposed over the channel feature in the Z-axis direction, and a second drain electrode disposed over the channel feature in the Z-axis direction;
wherein, for the second transistor, the first drain electrode is disposed at the first side of the source electrode in the X-axis direction, the second drain electrode is disposed at the second side of the source electrode in the X-axis direction;
wherein, for the second transistor, the channel feature has a first channel portion extending between and interconnecting the first drain electrode and the source electrode, and a second channel portion extending between and interconnecting the second drain electrode and the source electrode, and the gate electrode overlaps both of the first channel portion and the second channel portion of the channel feature in the Z-axis direction; and
wherein the channel features of the first transistor and the second transistor are formed in one piece.

3. The memory device according to claim 2, wherein the second drain electrode of the first transistor and the first drain electrode of the second transistor are formed in one piece.

4. The memory device according to claim 3, wherein, for the first transistor, the gate electrode overlaps one or both of the first drain electrode and the second drain electrode in the Z-axis direction.

5. The memory device according to claim 3, wherein, for the first transistor, the gate electrode is spaced apart from one or both of the first drain electrode and the second drain electrode in the X-axis direction.

6. The memory device according to claim 3, wherein, for the first transistor, each of the first drain electrode and the second drain electrode has a length in the X-axis direction greater than that of the source electrode.

7. The memory device according to claim 3, wherein, for the first transistor, each of the first drain electrode and the second drain electrode has a length in the X-axis direction smaller than that of the source electrode.

8. The memory device according to claim 3, wherein, for the first transistor, an overlap between the gate electrode and the first channel portion in the Z-axis direction has a length in the X-axis direction greater than or equal to two-thirds of a length of the first channel portion in the X-axis direction, and an overlap between the gate electrode and the second channel portion in the Z-axis direction has a length in the X-axis direction greater than or equal to two-thirds of a length of the second channel portion in the X-axis direction.

9. The memory device according to claim 3, wherein the channel feature of each of the first transistor and the second transistor includes at least one of IGZO, ZnO, In₂O₃, SnO₂, NiO, Cu₂O, CuAlO₂, CuGaO₂, CuInO₂, SrCu₂O₂, or SnO.

10. The memory device according to claim 3, further comprising a bit line that electrically interconnects the first drain electrodes and the second drain electrodes of the first transistor and the second transistor.

11. A memory device, comprising:
a first transistor including
a gate electrode formed on a semiconductor substrate,
a first drain electrode, a second drain electrode and a source electrode formed in one layer, arranged in an X-axis direction, and disposed above the gate electrode in a Z-axis direction that is transverse to the X-axis direction, wherein the source electrode is disposed between the first drain electrode and the second drain electrode,
a channel feature disposed between the gate electrode and said one layer where the first drain electrode, the second drain electrode and the source electrode are formed, and extending from the first drain electrode to the second drain electrode, and
a gate dielectric layer disposed between the gate electrode and the channel feature; and
a first capacitor electrically connected to the source electrode of the first transistor;
wherein the channel feature has a first channel portion extending between and interconnecting the first drain electrode and the source electrode, and a second channel portion extending between and interconnecting the second drain electrode and the source electrode, and the gate electrode overlaps both of the first channel portion and the second channel portion of the channel feature.

12. The memory device according to claim 11, further comprising:
a second transistor including
a gate electrode formed on the semiconductor substrate,
a first drain electrode, a second drain electrode and a source electrode formed in said one layer, arranged in the X-axis direction, and disposed above the gate electrode, wherein the source electrode of the second transistor is disposed between the first drain electrode of the second transistor and the second drain electrode of the second transistor,
a channel feature disposed between the gate electrode and said one layer, and extending from the first drain electrode to the second drain electrode, and
a gate dielectric layer disposed between the gate electrode and the channel feature; and
a second capacitor electrically connected to the source electrode of the second transistor;
wherein, for the second transistor, the channel feature has a first channel portion extending between and interconnecting the first drain electrode and the source electrode, and a second channel portion extending between and interconnecting the second drain electrode and the source electrode, and the gate electrode overlaps both of the first channel portion and the second channel portion of the channel feature; and
wherein the channel features of the first transistor and the second transistor are formed in one piece.

13. The memory device according to claim 12, wherein the second drain electrode of the first transistor and the first drain electrode of the second transistor are formed in one piece.

14. The memory device according to claim 13, wherein, for the first transistor, a spacing between the gate electrode and the first drain electrode in the X-axis direction ranges from zero to one-third of a length of the first channel portion in the X-axis direction, and a spacing between the gate electrode and the second drain electrode in the X-axis direction ranges from zero to one-third of a length of the second channel portion in the X-axis direction.

15. The memory device according to claim 13, wherein the channel feature of each of the first transistor and the second transistor includes at least one of IGZO, ZnO, In₂O₃, SnO₂, NiO, Cu₂O, CuAlO₂, CuGaO₂, CuInO₂, SrCu₂O₂, or SnO.

16. A method for fabricating a memory device, comprising steps of:
forming a plurality of gate electrodes that are arranged in an X-axis direction on a semiconductor substrate;
forming a gate dielectric layer over the gate electrodes in a Z-axis direction that is transvers to the X-axis direction;
forming a channel layer over the gate dielectric layer in the Z-axis direction, wherein the channel layer includes a plurality of channel features that are formed in one piece and that respectively overlap the gate electrodes in the Z-axis direction;
forming a first drain electrode, a second drain electrode and a source electrode over each of the channel features in the Z-axis direction, wherein the first drain electrode, the second drain electrode and the source electrode are arranged in the X-axis direction with the source electrode being disposed between the first drain electrode and the second drain electrode; and
with respect to each of the channel features, forming a storage capacitor that is electrically connected to the source electrode which is disposed over the channel feature.

17. The method according to claim 16, wherein the channel features include a first channel feature and a second channel feature that are adjacent in the X-axis direction, and the second drain electrode formed on the first channel feature and the first drain electrode formed on the second channel feature are formed in one piece.

18. The method according to claim 17, wherein each of the channel features includes a first channel portion extending from the first drain electrode formed on the channel feature to the source electrode formed on the channel feature, and a second channel portion extending from the second drain electrode formed on the channel feature to the source electrode formed on the channel feature; and
wherein each of the gate electrodes overlaps both of the first channel portion and the second channel portion of the respective one of the channel features in the Z-axis direction.

19. The method according to claim 18, wherein, for each of the channel features, an overlap between the first channel portion of the channel feature and the respective one of the gate electrodes has a length in the X-axis direction greater than or equal to two-thirds of a length of the first channel portion in the X-axis direction, and an overlap between the second channel portion of the channel feature and the respective one of the gate electrodes has a length in the X-axis direction greater than or equal to two-thirds of a length of the second channel portion in the X-axis direction.

20. The method according to claim 17, wherein the channel layer includes at least one of IGZO, ZnO, In₂O₃, SnO₂, NiO, Cu₂O, CuAlO₂, CuGaO₂, CuInO₂, SrCu₂O₂, or SnO.
